(19) United States
(12) Patent Application Publication
(10) Pub. No.: US 2026/0324161 A1
(43) Pub. Date: Oct. 15, 2026

(54) DISPLAY MODULE AND ELECTRONIC DEVICE INCLUDING THE SAME

(71) Applicant: Samsung Electronics Co., Ltd., Suwon-si, Gyeonggi-do (KR)

(72) Inventors: Yeonghyeon SEO, Suwon-si (KR); Hyuntae JANG, Suwon-si (KR)

(21) Appl. No.: 19/684,402

(22) Filed: May 21, 2026

Related U.S. Application Data
(63) Continuation of application No. PCT/KR2026/095945, filed on Apr. 15, 2026.

(30) Foreign Application Priority Data
Apr. 15, 2025 (KR) 10-2025-0048728
Apr. 25, 2025 (KR) 10-2025-0054566

(51) Int. Cl. H10H 29/80; H10H 29/851; H10H 29/855

(52) U.S. Cl. CPC H10H 29/8323; H10H 29/851; H10H 29/8552

(57) ABSTRACT

A display module is provided. The display module includes a glass substrate including a first surface, a second surface opposite to the first surface, and a plurality of through holes extending from the second surface to the first surface, a plurality of through electrodes, each through electrode partially filling a through hole among the plurality of through holes, and a plurality of micro light emitting diodes (LEDs), each micro LED disposed in a through hole among the plurality of through holes, and electrically connected to a through electrode among the plurality of through electrodes.

### CROSS-REFERENCE TO RELATED APPLICATIONS

This application is a continuation application, claiming priority under 35 U.S.C. § 365(c), of an International application No. PCT/KR2026/095945, filed on Apr. 15, 2026, which is based on and claims the benefit of a Korean patent application number 10-2025-0048728, filed on Apr. 15, 2025, in the Ministry of Intellectual Property (MOIP), and of a Korean patent application number 10-2025-0054566, filed on Apr. 25, 2025, in the Ministry of Intellectual Property (MOIP), the disclosure of each of which is incorporated by reference herein in its entirety.

### TECHNICAL FIELD

The disclosure relates to a display module and an electronic device including the same.

### BACKGROUND ART

Light emitting diodes (LEDs) are used across various industrial sectors, and their relatively high luminous efficiency and long lifespan make application and use practical not only in general lighting purposes but also in the display field.

Micro LEDs, as next-generation light-emitting elements, offer higher efficiency than liquid crystal displays (LCDs), LEDs, and similar to organic light emitting diodes (OLEDs) and do not require additional filtering or conversion to directly emit pure colors from sub-pixels. A display module applying the micro LEDs may achieve a wide viewing angle, high efficiency, vivid colors, and high definition.

A plurality of pixels is arranged in a display module. Each pixel is composed of three R/G/B sub-pixels. A sub-pixel is typically based on a blue LED and includes a phosphor formed on a light-emitting surface of the blue LED to emit a desired color (e.g., red, green) for each sub-pixel. The LED that emits blue light employs only the blue LED without such a phosphor.

The above information is presented as background information only to assist with an understanding of the disclosure. No determination has been made, and no assertion is made, as to whether any of the above might be applicable as prior art with regard to the disclosure.

### DISCLOSURE OF INVENTION

### Technical Solution

Aspects of the disclosure are to address at least the above-mentioned problems and/or disadvantages and to provide at least the advantages described below. Accordingly, an aspect of the disclosure is to provide a display module and an electronic device including the same.

Additional aspects will be set forth in part in the description which follows and, in part, will be apparent from the description, or may be learned by practice of the presented embodiments.

In accordance with an aspect of the disclosure, a display module is provided. The display module includes a glass substrate including a first side (e.g., surface), a second side (e.g., surface) opposite to the first side (e.g., surface), and a plurality of through holes extending from the second side (e.g., surface) to the first side (e.g., surface), a plurality of through electrodes, each through electrode partially filling a through hole among the plurality of through holes, and a plurality of micro LEDs, each micro LED disposed in a through hole among the plurality of through holes, and electrically connected to a through electrode among the plurality of through electrodes.

In accordance with another aspect of the disclosure, an electronic device is provided. The electronic device includes one or more display modules, and a driver integrated circuit (IC) configured to generate a driving signal to be supplied to the one or more display modules, wherein each display module among the one or more display modules comprises a glass substrate including a first side (e.g., surface) and a second side (e.g., surface) opposite to the first side (e.g., surface), the glass substrate including a plurality of through holes extending from the second side (e.g., surface) to the first side (e.g., surface), a plurality of through electrodes, each through electrode partially filling a through hole among the plurality of through holes, and a plurality of micro LEDs, each LED disposed in a through hole among the plurality of through holes and electrically connected to a through electrode among the plurality of through electrodes.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to various embodiments;

FIG. 2 is a plan view of a display device according to an embodiment of the disclosure;

FIG. 3 is a diagram illustrating an example of a pixel array making up a unit module of a display device according to an embodiment of the disclosure;

FIG. 4 is a cross-sectional view of a display module according to an embodiment of the disclosure;

FIG. 5 is an enlarged view of portion A shown in FIG. 4 according to an embodiment of the disclosure;

FIG. 6 is a cross-sectional view of a display module according to an embodiment of the disclosure;

FIGS. 7A and 7B are diagrams illustrating various examples of a layer structure of a display module according to various embodiments of the disclosure;

FIG. 8 is a cross-sectional view of a display module according to an embodiment of the disclosure; and

FIG. 9 is a cross-sectional view of a display module according to an embodiment of the disclosure.

Throughout the drawings, it should be noted that like reference numbers are used to depict the same or similar elements, features, and structures.

### MODE FOR THE INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms used and words in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

As used herein, each of the phrases such as “A or B”, “at least one of A and B”, “at least one of A or B”, “A, B or C”, “at least one of A, B and C”, and “at least one of A, B, or C” may include any one of the items enumerated together in a corresponding one of the phrases, or all possible combinations thereof. Further, it should be appreciated that the term ‘and/or’ used herein encompasses any and all possible combinations of one or more of the listed items. The expressions such as “first”, “second”, and the like used herein may be used to distinguish one component from other components, and do not limit the corresponding components in view of other aspect (e.g., importance or order).

When an element (e.g., a first element) is referred to as being "coupled," "connected," "joined," "combined," "supported," "accessed," or "in contact" with another element (e.g., a second element), with or without the term "operatively” or "communicatively", it includes not only the case where the element is directly coupled, connected, joined, combined, supported, accessed, or in contact with the other element, but also the case where the element is indirectly coupled, connected, joined, combined, supported, accessed, or in contact with the other element via a third element."

As used herein, the terms such as “comprise”, “include”, or “have” are only intended to designate that there are features, numbers, steps, operations, components, parts, or a combination thereof described in the disclosure, and are not intended to exclude in advance a possibility of the presence or addition of one or more other features, numbers, steps, operations, components, parts, or a combination thereof, by using these terms. When a certain component is described as being positioned "on" another component, it includes not only the case where the certain component is in contact with the other component, but also the case where another component exists between the two components.

As used in the disclosure, the expression “configured to ~” may be used interchangeably with, depending on the context, for example, “suitable for ~”, “having the ability to ~”, “designed to ~”, “modified to ~”, “made to ~”, “capable of ~” or the like. The term “configured to ~” may not necessarily mean only “specially designed to ~” in hardware. Instead, in some situations, the expression “a device configured to ~” may mean that the device is “capable of ~” together with another devices or components. For example, a phrase “a device configured (or adapted) to perform A, B, and C” may refer to a dedicated device for performing a corresponding operation or refer to a general-purpose device capable of performing various operations including the corresponding operation.

The terms such as e.g., “upper side”, “lower side”, “forward/backward direction” and the like used in the disclosure are defined on the basis of the accompanying drawings, and the shape and position of the corresponding component are not limited by these terms.

While the description as set forth in the disclosure is made focused on specific embodiments, it is to be appreciated that the disclosure is not limited to such specific embodiments but encompasses all various modifications, equivalents, and/or substitutions of the various embodiments described herein. With regard to the description of the drawings, similar reference numerals may be used for similar or related elements.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

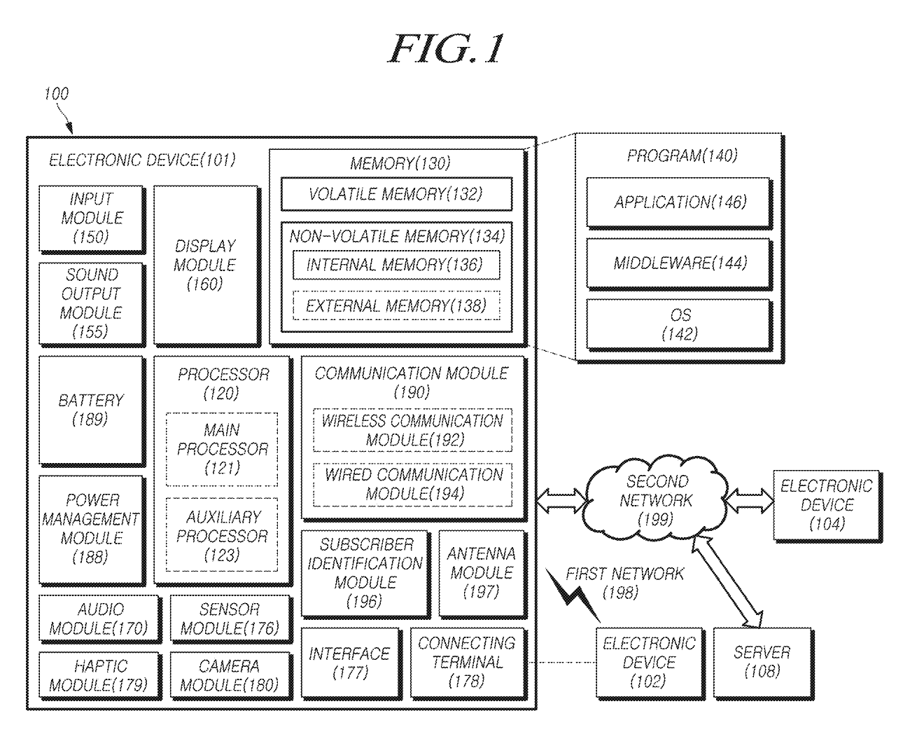

FIG. 1 is a block diagram of an electronic device 101 in a network environment 100 according to various embodiments of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one of the components (e.g., the connecting terminal 178) may be omitted from the electronic device 101, or one or more other components may be added in the electronic device 101. In an embodiment, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may, for example, control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The data may include, for example, software (e.g., the program 140) and input data or output data for a command related thereto. The memory 130 may include the volatile memory 132 or the non-volatile memory 134. The non-volatile memory 134 includes an internal memory 136 and may include external memory 138.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or an external electronic device (e.g., the electronic device 102)(e.g., speaker or headphone) directly or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

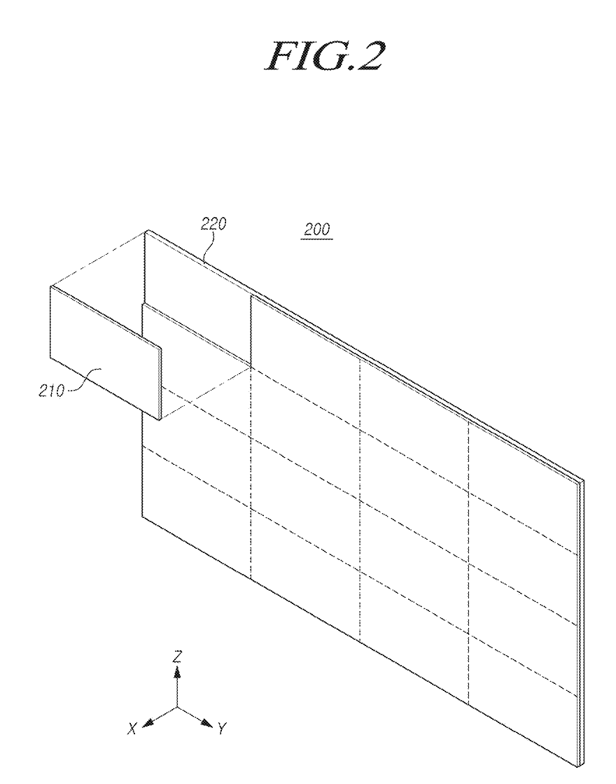

FIG. 2 is a plan view of a display device according to an embodiment of the disclosure.

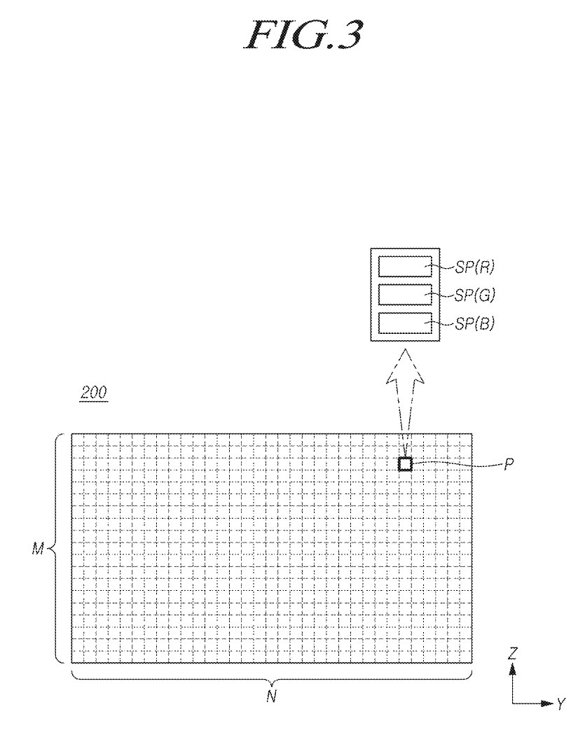

FIG. 3 is a diagram illustrating an example of a pixel array making up a unit module of a display device according to an embodiment of the disclosure.

The embodiments of FIGS. 2 and 3 may be selectively combined with the embodiment of FIG. 1.

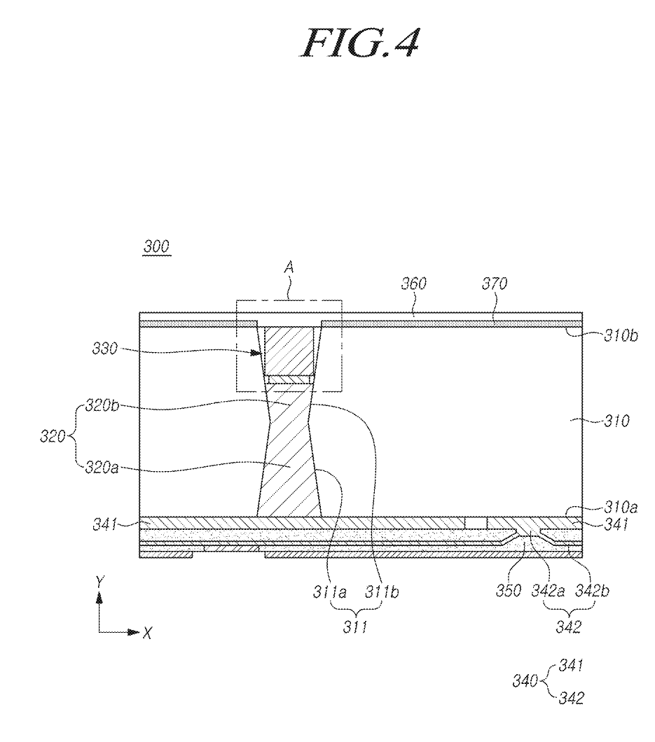

According to an embodiment, an electronic device 200 (e.g., the electronic device 101 of FIG. 1) is a self-emissive display device in which a light-emitting element (e.g., a micro LED 330 of FIG. 4) is arranged for each pixel P so that the pixel can emit light by itself. As opposed to a LCD device, such a self-emissive display device does not require components such as a backlight unit, a liquid crystal layer and the like, so it is possible to realize a thin (e.g., minimal) thickness, and its simple structure allows for various design changes.

According to an embodiment, the display device 200 may employ an inorganic light-emitting element, such as an inorganic LED, as the light-emitting element disposed in each pixel. The inorganic light-emitting element has a faster response speed and may implement higher luminance with low power consumption, compared to an organic light-emitting element such as an OLED. Unlike the organic light-emitting elements, which are vulnerable to exposure to moisture and oxygen, requiring an encapsulation process and having weak durability, the inorganic light-emitting element does not require an encapsulation process and provides strong durability. Hereinafter, the inorganic light-emitting element mentioned in the following embodiments will be assumed to refer to an inorganic LED.

According to an embodiment, the inorganic light-emitting element employed in the display device 200 may include a micro LED having a short side length of approximately 100 μm, or a size of about tens of μm, or a size of a few μm. By employing LEDs in micro units in this manner, the pixel size may be reduced and high resolution may be realized even within the same screen size.

According to an embodiment, in case that the LED chip is manufactured in micro unit size, the problem of cracking upon bending, which is characteristic of inorganic materials, may be addressed. In other words, in case that the micro LED chip is transferred onto a flexible substrate, in case a substrate is bent, the LED chip is not broken, so that a flexible display device can also be implemented.

According to an embodiment, a display device employing a micro LED may be applied in various technical fields utilizing its ultra-small pixel size and thin thickness. For example, as shown in FIG. 2, a large-area screen may be realized by tiling a plurality of display modules 210 with a plurality of micro LEDs transferred thereon and fixing them to a main body 220, and the display device 200 with such a large-area screen may be used as a signage, an electronic signboard, or the like.

The three-dimensional coordinate system of XYZ axes shown in FIG. 2 is based on the display device 200, where the plane on which the screen of the display device 200 is located is XZ plane, and the direction in which an image is output or the light-emitting direction of the inorganic light-emitting element is +Y direction. Since the coordinate system is based on the display device 200, the same coordinate system may be applied whether the display device 200 is lying down or standing up.

According to an embodiment, the display device 200 is generally used in an upright state, and since a user views an image from the front of the display device 200, the +Y direction where the image is output may be referred to as the front, and the opposite direction may be referred to as the rear.

According to an embodiment, the display device 200 is generally manufactured in a lying state. Therefore, it is also possible to refer to -Y direction of the display device 200 as a lower direction and +Y direction as an upper direction. That is, in one or more embodiment(s) described later, the +Y direction may be referred to as the upper direction or the front, and the -Y direction may be referred to as the lower direction or the rear.

The four remaining sides of the flat-type display device 200 or the display module 210, excluding the top and bottom sides (e.g., surfaces), are all referred to as lateral sides (e.g., lateral surfaces or side surfaces), regardless of the posture of the display device 200 or the display module 210.

The example of FIG. 2 illustrates a case where the display device 200 realizes a large-area screen including a plurality of display modules, but the embodiment of the display device 200 is not limited thereto. The display device 200 may also be implemented as a single display module 210 to be used as a television (TV), a wearable device, a portable device, a PC monitor, or the like.

Referring to FIG. 3, the display module 210 may include an M x N array of pixels, wherein M and N are integers of 2 or more, that is, a plurality of pixels arrayed in two dimensions. FIG. 3 conceptually illustrates such an array of pixels, and it will be apparently appreciated that, in addition to the active area where the pixels are arranged on the display module 210, a bezel area, a wiring area, or the like, where images are not displayed, may also be located.

In the corresponding embodiments, the fact that certain components are arranged in two dimensions is to be understood as including not only the case where the corresponding components are disposed on the same plane but also the case where they are disposed on different planes parallel to each other. Furthermore, in the case where the corresponding components are disposed on the same plane, the top sides (e.g., surfaces) of the components disposed are not necessarily located on the exact same plane and they may be located on another plane parallel to each other.

The pixel P may include a plurality of sub-pixels that output light of different colors to realize various colors using a color combination. For example, the pixel may be composed of at least three sub-pixels that output light of different colors. More specifically, the pixel P may be composed of three sub-pixels (SP(R), SP(G), and SP(B)) corresponding to the colors R, G, and B, respectively. Here, the red sub-pixel (SP(R)) may output red light, the green sub-pixel (SP(G)) may output green light, and the blue sub-pixel (SP(B)) may output blue light.

The pixel arrangement illustrated in FIG. 3 is merely an example that may be applied to the display module 210 and the display device 200 according to an embodiment, and the sub-pixels may be arranged along an X-axis direction, may not be arranged in a row, or may be implemented in different sizes of sub-pixels. In order for a single pixel to implement a variety of colors, it only needs to include a plurality of sub-pixels, and there is no restriction on the size or arrangement method of each sub-pixel.

Further, the pixel P does not necessarily have to be composed of a red sub-pixel SP(R) that outputs red light, a green sub-pixel SP(G) that outputs green light, and a blue sub-pixel SP(B) that outputs blue light, and it may include a sub-pixel that outputs either yellow light or white light. In other words, there is no restriction on the color or type of light output from each sub-pixel, not on the number of sub-pixels.

However, for the purpose of a detailed description in the embodiments described below, a case where the pixel P is composed of the red sub-pixel (SP(R)), the green sub-pixel (SP(G)), and the blue sub-pixel (SP(B)) will be described as an example.

As mentioned above, the display module 210 and the display device 200 according to an embodiment are self-emissive display devices where each pixel may emit light by itself. Accordingly, an inorganic light-emitting element that emits light of a different color may be disposed in each sub-pixel. For example, a red inorganic light-emitting element may be disposed in the red sub-pixel (SP(R)), a green inorganic light-emitting element may be disposed in the green sub-pixel (SP(G)), and a blue inorganic light-emitting element may be disposed in the blue sub-pixel (SP(B)).

According to an embodiment, the pixel P may represent a cluster including the red inorganic light-emitting element, the green inorganic light-emitting element, and the blue inorganic light-emitting element, and the sub-pixel may represent each inorganic light-emitting element.

Although not explicitly illustrated in the drawings, the display device 200 may include a driver IC (not shown) configured to generate a driving signal to be supplied to the one or more display modules 210.

FIG. 4 is a cross-sectional view of a display module according to an embodiment of the disclosure.

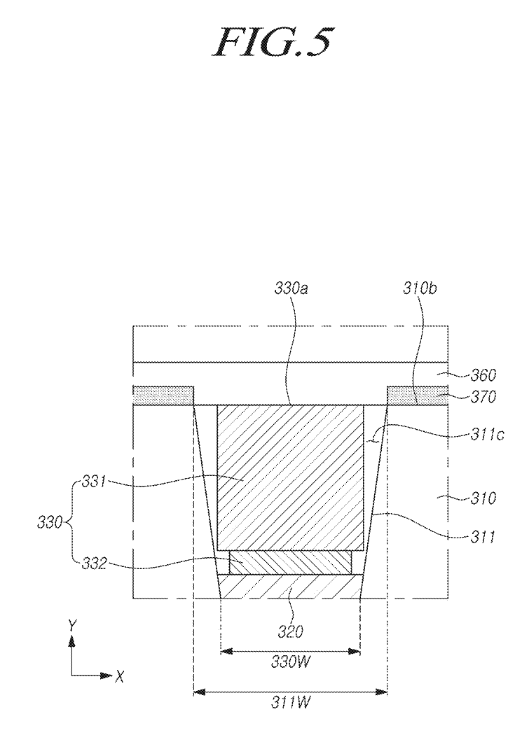

FIG. 5 is an enlarged view of a portion A shown in FIG. 4 according to an embodiment of the disclosure.

The embodiments of FIGS. 4 and 5 may be selectively combined with the embodiments of FIGS. 1-3.

The configuration of the display device 300 of FIGS. 4 and 5 may be entirely or partially the same as the configuration of the display device 200 of FIGS. 2 and 3.

Referring to FIGS. 4 and 5, the display device 300, according to an embodiment, may include a substrate 310, a plurality of through electrodes 320, a plurality of micro LEDs 330, a wiring pattern layer 340, an insulation layer 350, a transparent electrode layer 360, or a black matrix layer 370.

According to an embodiment, the glass substrate 310 may include a first side 310a and a second side 310b opposite to the first side 310a. For example, the first side 310a of the glass substrate 310 may be referred to as a lower side (e.g., surface) of the glass substrate 310, and the second side 310b may be referred to as an upper side (e.g., surface) of the glass substrate 310.

According to an embodiment, the glass substrate 310 may be designed to have a thickness of about 0.5 mm, but the disclosure is not limited thereto.

According to an embodiment, the glass substrate 310 may include a plurality of through holes 311. The through holes 311 may be formed through various etching processes, such as etching using an etchant (e.g., hydrofluoric acid), or etching using a laser (e.g., laser induced etching (LIE), laser induced deep etching (LIDE)).

According to an embodiment, the through holes 311 may extend from the first side 310a to the second side 310b of the glass substrate 310. The through holes 311 may have a diameter that changes as it goes from the first side 310a toward the second side 310b, as shown in FIG. 4.

According to an embodiment, the through hole 311 may include a first portion 311a whose diameter gradually decreases as it goes from the first side 310a toward the second side 310b, and a second portion 311b whose diameter gradually increases as it goes from the first side 310a toward the second side 310b. For example, the first portion 311a of the through hole 311 may be formed by an etching process (e.g., a first etching process) on the first side 310a of the glass substrate 310. For example, the second portion 311b of the through hole 311 may be formed by an etching process (e.g., a second etching process) on the second side 310b of the glass substrate 310. That is, the first portion 311a and the second portion 311b of the through hole 311 may be formed separately through different etching processes to make up a single through hole 311. However, the disclosure is not limited thereto, and the through hole 311 may be integrally formed through a single etching process.

According to an embodiment, the through electrode 320 may be partially disposed in the through hole 311. For example, the through electrode 320 may be filled inside 311c the through hole 311 across the first portion 311a and the second portion 311b of the through hole 311. The through electrode 320 may include a first electrode portion 320a corresponding to the first portion 311a of the through hole 311, and a second electrode portion 320b partially corresponding to the second portion 311b of the through hole 311. The size of the second electrode portion 320b of the through electrode 320 may be designed to be smaller than that of the first electrode portion 320a.

According to an embodiment, the through electrode 320 may be formed through a VIA filling, which involves plating the inner wall of the through hole 311 with a conductive material (e.g., copper) and then filling the through hole 311 with a filling material. Here, the filling material may be the same material as the conductive material. For example, the through electrode 320 may be composed of a conductive material made of a combination of one or more of gold (Au), silver (Ag), copper (Cu), aluminum (Al), tungsten (W), and nickel (Ni). The through electrode 320 may be referred to as a through glass via (TGV).

According to an embodiment, the through electrode 320 can transmit an electrical signal received from the lower side of the glass substrate 310 to the upper side of the glass substrate 310. For example, the upper part (e.g., the second electrode portion 320b) of the through electrode 320 may be electrically connected to the micro LED 330. For example, the lower part (e.g., the first electrode portion 320a) of the through electrode 320 may be electrically connected to the wiring pattern layer 340 (e.g., a pad 341).

According to an embodiment, the micro LED 330 may be made of an inorganic light-emitting material having a size of 100µm or less. The micro LED 330 may be a semiconductor chip that can emit light by itself in case power is supplied. Both the OLED and the micro LED 330, which is an inorganic light-emitting element, have good energy efficiency, but the micro LED 330 has better brightness, luminous efficiency, and lifespan than those of the OLED. The display module 300 equipped with a plurality of micro LEDs 330 may provide better contrast, faster response time, and higher energy efficiency compared to a LCD panel which requires a backlight.

According to an embodiment, the micro LED 330 may be disposed in the through hole 311. The micro LED 330 may be positioned on the upper side of the through electrode 320 within the through hole 311.

According to an embodiment, the horizontal width 330W of the micro LED 330 may be designed to be smaller than the diameter 311W of the through hole 311. Therefore, the micro LED 330 may be inserted into the through hole 311 and positioned inside the through hole 311. In conjunction with the manufacturing process of the display module 300, the micro LED 330 is transferred (e.g., disposed) into the through hole 311 and stably fixed within the through hole 311, so a stable electrical connection of the display module 300 can be secured.

According to an embodiment, the micro LED 330 may include an upper side 330a that is substantially coplanar with the second side 310b of the glass substrate 310. The upper side 330a of the micro LED 330 substantially coplanar with the second side 310b of the glass substrate 310 may eliminate or minimize the step difference in the upper layer of the glass substrate 310, thereby enabling realization of a thin profile of the display module 300. The upper layer of the glass substrate 310 may include layers stacked on the second side 310b of the glass substrate 310, such as a transparent electrode layer 360 and/or a black matrix layer 370. Unlike the illustration in the drawings, the upper side 330a of the micro LED 330 may also be positioned below the second side 310b of the glass substrate 310 (e.g., in the -Y axis direction).

According to an embodiment, the positional relationship between the upper side 330a of the micro LED 330 and the second side 310b of the glass substrate 310 may vary depending on a filling amount of the through electrode 320. For example, in case the filling amount of the through electrode 320 decreases, the height of the through electrode 320 decreases and the upper side 330a of the micro LED 330 may then move away from the second side 310b of the glass substrate 310. For example, in case that the filling amount of the through electrode 320 increases, the height of the through electrode 320 increases and the upper side 330a of the micro LED 330 may then move closer to the second side 310b of the glass substrate 310.

According to an embodiment, the micro LED 330 may be a vertical micro LED. Unlike a horizontal micro LED (e.g., a flip-chip LED), the vertical micro LED may include an upper electrode (not shown) (e.g., an anode) provided on an upper part of the LED chip and a lower electrode (not shown) (e.g., a cathode) provided on a lower part thereof. For example, the micro LED 330 may be electrically connected to the transparent electrode layer 360 through the upper electrode (not shown). For example, the micro LED 330 may be electrically connected to the through electrode 320 via the lower electrode (not shown).

In the case of the horizontal micro LED, area constraints may arise because a via (e.g., the through electrode 320) and a separate pad (not shown) are required on the second side 310b of the glass substrate 310 for electrical connection within the display module, and there are limitations in achieving fine pitch between LEDs as a result. In contrast, in the case of the vertical micro LED, the electrodes may be formed vertically, freeing it from spatial constraints and then making it suitable for high-resolution displays.

According to an embodiment, the micro LED 330 may include an LED chip 331 and a connecting member 332. The LED chip 331 may be configured to emit red, green, or blue light. The connecting member 332 may be connected to a lower electrode (not shown) of the LED chip 331. The connecting member 332 may physically or electrically connect the LED chip 331 and the through electrode 320. The connecting member 332 may be, for example, a solder bump or a solder ball. For example, the connecting member 332 may be integrally provided on the lower side (e.g., surface) of the LED chip 331 and coupled to the through electrode 320, or provided on the upper side (e.g., surface) of the through electrode 320 and coupled to the LED chip 331.

According to an embodiment, the wiring pattern layer 340 may be disposed on the first side 310a of the glass substrate 310. The wiring pattern layer 340 may be formed of a conductive material such as copper. The wiring pattern layer 340 may include a plurality of pads 341 and a plurality of circuit patterns 342.

According to an embodiment, the pad 341 may be electrically connected to the through electrode 320. For example, the pad 341 may be disposed on the first side 310a of the glass substrate 310 so as to cover the lower side of the through electrode 320. The pad 341 may have, for example, a circular or square planar shape. Accordingly, the cross-section of the pad 341 may have a horizontally elongated rectangular shape.

According to an embodiment, the circuit pattern 342 may be electrically connected to the pad 341. The circuit pattern 342 may include a via 342a extending vertically from the pad 341 and a line pattern 342b extending slantingly or horizontally from the via.

According to an embodiment, the insulation layer 350 may be disposed to surround the wiring pattern layer 340. The insulation layer 350 may maintain an electrically insulating state of the electrodes and wirings so that those electrodes and wirings do not short-circuit with each other. For example, the insulation layer 350 may include photosensitive resin (PSR), polyimide (PI), silicon nitride (SiNx), or silicon oxide (SiOx).

According to an embodiment, the transparent electrode layer 360 may be disposed on the upper side of the glass substrate 310. For example, the transparent electrode layer 360 may be disposed on the upper side of the glass substrate 310 so as to cover a plurality of LEDs 330 and/or the black matrix layer 370. The transparent electrode layer 360 may be understood as a common electrode layer for a plurality of micro LEDs 330. For example, the transparent electrode layer 360 may be electrically connected to the upper electrode (not shown) of each micro LED 330. The transparent electrode layer 360 may be formed of a conductive transparent material including at least one of, for example, indium tin oxide (ITO), indium tin zinc oxide (ITZO), silver nano wire (AgNW), and poly-ethylene dioxythiophene (PEDOT).

According to an embodiment, the black matrix layer 370 may be disposed on the second side 310b of the glass substrate 310. The black matrix layer 370 may be disposed between the glass substrate 310 and the transparent electrode layer 360. The black matrix layer 370 may be configured to block light in areas excluding the upper areas of the plurality of micro LEDs 330. The black matrix layer 370 may be disposed between the pixels (e.g., the micro LEDs 330) to reduce the phenomenon of color bleeding in which ambient light leaks out from the inside of the display module 300 or spreads to neighboring pixels. Further, the black matrix layer 370 may improve the contrast between dark and bright regions of the display module 300. The black matrix layer 370 may be formed by combining one or more of, for example, carbon black, inorganic pigments, and polymer binder.

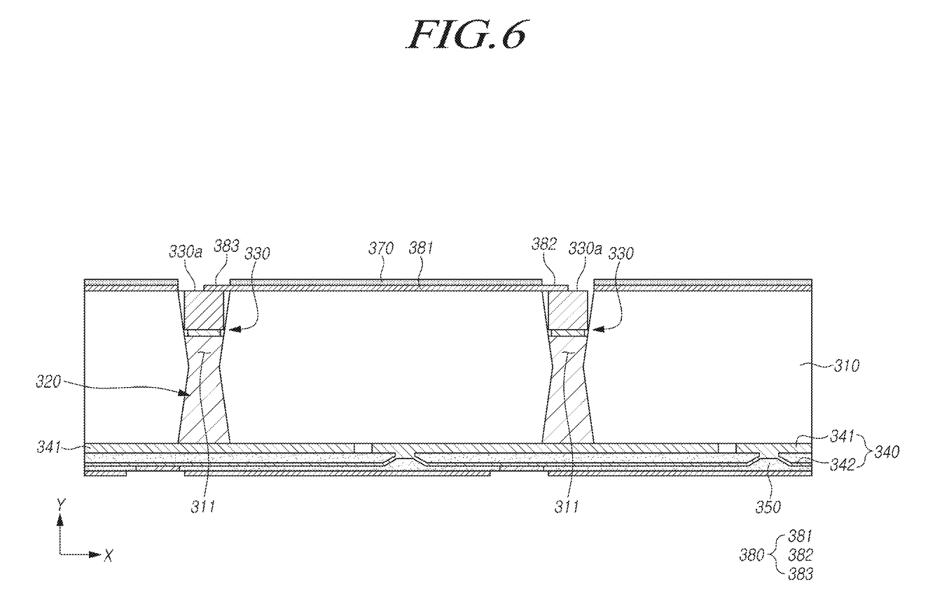

FIG. 6 is a cross-sectional view of a display module according to an embodiment of the disclosure.

The embodiment of FIG. 6 may be selectively combined with the embodiments of FIGS. 1-5.

Referring to FIG. 6, a display module 300, according to an embodiment, may include a glass substrate 310, a plurality of through electrodes 320, a plurality of micro LEDs 330, a first wiring pattern layer 340, an insulation layer 350, a black matrix layer 370, or a second wiring pattern layer 380.

The configuration of the first wiring pattern layer 340 of FIG. 6 may be entirely or partially the same as the configuration of the wiring pattern layer 340 of FIG. 4.

According to an embodiment, the first wiring pattern layer 340 may be disposed on the first side 310a of the glass substrate 310. The first wiring pattern layer 340 may be electrically connected to the lower electrodes (not shown) of the plurality of micro LEDs 330 via the through electrodes 320.

According to an embodiment, the second wiring pattern layer 380 may be disposed on the second side 310b of the glass substrate 310. The second wiring pattern layer 380 may be electrically connected to the upper electrodes (not shown) of the plurality of micro LEDs 330. For example, the second wiring pattern layer 380 of FIG. 6 may be configured to replace the transparent electrode layer 360 of FIG. 4.

According to an embodiment, the second wiring pattern layer 380 may include a line pattern 381 and connecting parts 382 and 383 extending to both sides of the line pattern 381. The line pattern 381 of the second wiring pattern layer 380 may be disposed over a remaining region of the glass substrate 310, excluding the through holes 311 of the glass substrate 310. The black matrix layer 370 may be disposed on the line pattern 381 of the second wiring pattern layer 380. The connecting parts 382 and 383 of the second wiring pattern layer 380 may extend horizontally from both sides of the line pattern 381 of the second wiring pattern layer 380. The connecting parts 382 and 383 of the second wiring pattern layer 380 may be partially positioned on the upper side of the micro LED 330. Each of the connecting parts 382 and 383 of the second wiring pattern layer 380 may be electrically connected to the upper electrode (not shown) of the micro LED 330. Although not explicitly illustrated in this drawing, the connecting parts 382 and 383 of the second wiring pattern layer 380 may be line-shaped connection parts protruding or extending from the line pattern 381.

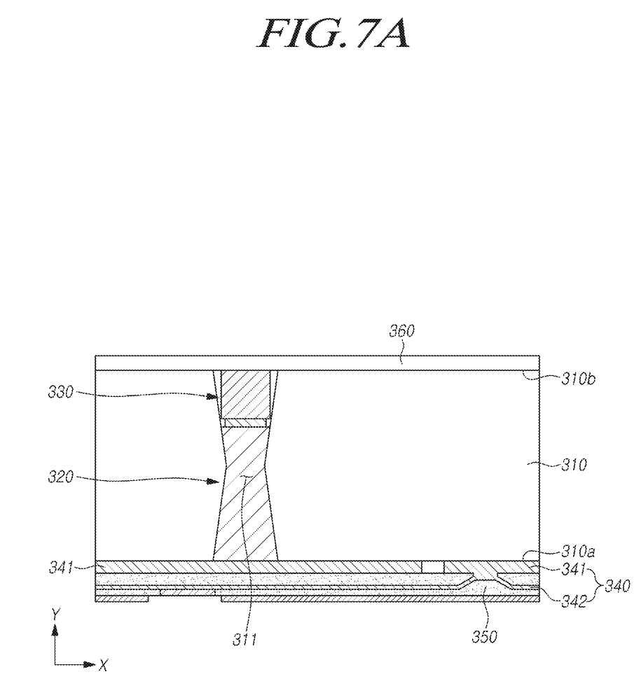

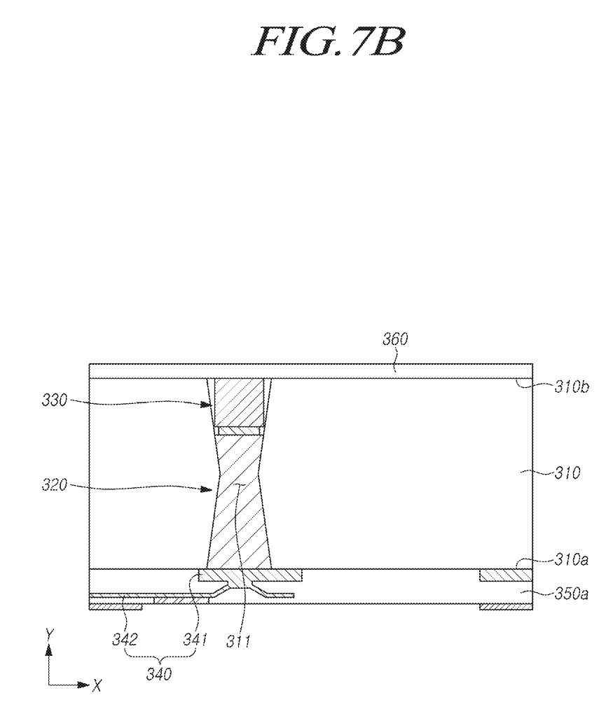

FIGS. 7A and 7B are diagrams illustrating various examples of a layer structure of a display module according to various embodiments of the disclosure.

The embodiments of FIGS. 7A and 7B may be selectively combined with the embodiments of FIGS. 1-6.

Referring to FIGS. 7A and 7B, a display module 300 according to an embodiment may include a glass substrate 310, a plurality of through electrodes 320, a plurality of micro LEDs 330, a wiring pattern layer 340, an insulation layer 350 or 350a, or a transparent electrode layer 360.

According to an embodiment, the display module 300 of FIGS. 7A and 7B may not include a black matrix layer (e.g., the black matrix layer 370 of FIG. 4), as opposed to the aforementioned display module 300 of FIGS. 4-6.

For example, the black matrix layer may be omitted in the display module 300 in case that light leakage is in a low level or deep black expression (e.g., the degree to which the display can express black deeply and richly) is not required.

Referring to FIG. 7A, in case the black matrix layer is removed from the display module 300, the transparent electrode layer 360 may be disposed on the second side 310b of the glass substrate 310.

For example, the black matrix layer may be omitted to ensure transparency in case that the display module 300 is implemented as a transparent display.

Referring to FIG. 7B, in case the display module 300 is implemented as a transparent display, the insulation layer 350a of the display module 300 may be formed of an oxide-based transparent material or a polymer-based material for light transmission, but the disclosure is not limited thereto. Accordingly, in case the display screen is implemented as transparent, a user may see an object on the opposite side of the transparent display module 300 through the display screen.

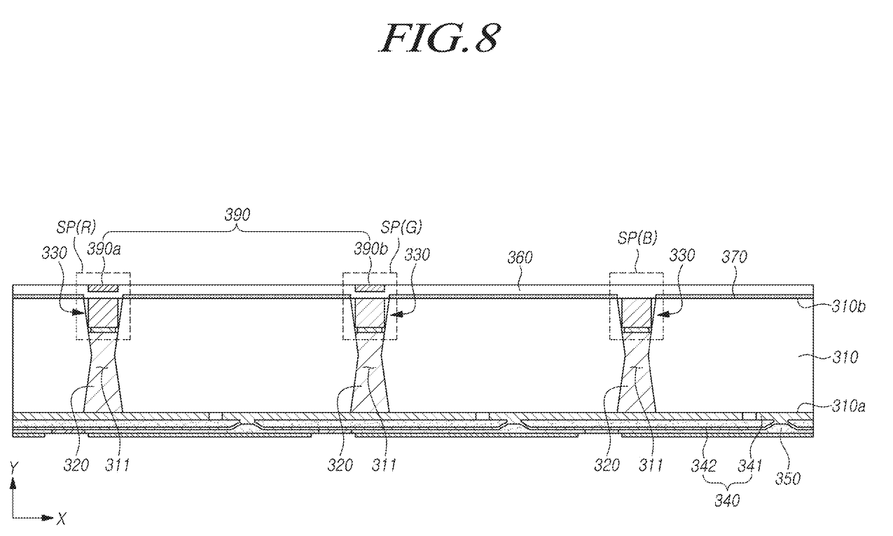

FIG. 8 is a cross-sectional view of a display module according to an embodiment of the disclosure.

The embodiment of FIG. 8 may be selectively combined with the embodiments of FIGS. 1-6, 7A, and 7B.

Referring to FIG. 8, a display module 300, according to an embodiment, may include a glass substrate 310, a plurality of through electrodes 320, a plurality of micro LEDs 330, a wiring pattern layer 340, an insulation layer 350, a transparent electrode layer 360, a black matrix layer 370, or a plurality of color conversion layers 390.

According to an embodiment, the plurality of micro LEDs 330 may include blue light micro LEDs configured to emit blue light.

According to an embodiment, the color conversion layer 390 may be configured to absorb most of the light emitted from the corresponding micro LED 330 and emit light of a different color than the absorbed light. The plurality of color conversion layers 390 may include a first color conversion layer 390a and a second color conversion layer 390b that emit light in different wavelength bands.

For example, the first color conversion layer 390a may include a red nanophosphor that may be excited by light in a blue wavelength band emitted from the micro LED 330 and emit light in a red wavelength band. For example, the first color conversion layer 390a may be made of a material including red quantum dots that emit light in the red wavelength band, as an alternative to the red nanophosphor. The first color conversion layer 390a may be referred to as a red conversion layer.

For example, the second color conversion layer 390b may include a green nanophosphor that may be excited by light in a blue wavelength band emitted from the micro LED 330 and emit light in a green wavelength band. For example, the second color conversion layer 390b may be made of a material including green quantum dots that emit light in the green wavelength band, as an alternative to the green nanophosphor. The second color conversion layer 390b may be referred to as a green conversion layer.

According to an embodiment, the plurality of color conversion layers 390 may be disposed on the transparent electrode layer 360. The plurality of color conversion layers 390 may be positioned on the upper side of some of the plurality of micro LEDs 330. For example, the plurality of color conversion layers 390 may be disposed on the upper side of the three micro LEDs 330 that make up one pixel (e.g., the pixel P of FIG. 3). In such a case, the three micro LEDs 330 and the two color conversion layers 390 may make up the sub-pixels (SP(R), SP(G), SP(B)) of the display module 300.

For example, one of the three micro LEDs 330 and one color conversion layer corresponding to the micro LED 330 (e.g., the first color conversion layer 390a) may make up the red sub-pixel (SP(R)) that emits red light.

For example, another one of the three micro LEDs 330 and the remaining color conversion layer corresponding to the micro LED 330 (e.g., the second color conversion layer 390b) may make up the green sub-pixel (SP(G)) that emits green light.

For example, the remaining one of the three micro LEDs 330 may make up the blue sub-pixel (SP(B)) that emits blue light by itself without any corresponding color conversion layer 390.

As described above, by implementing red, green, and blue (RGB) colors through a single unified blue light micro LED 330 and its corresponding color conversion layers 390a and 390b in the display module 300, it is possible to simplify the manufacturing process and achieve high-purity RGB colors.

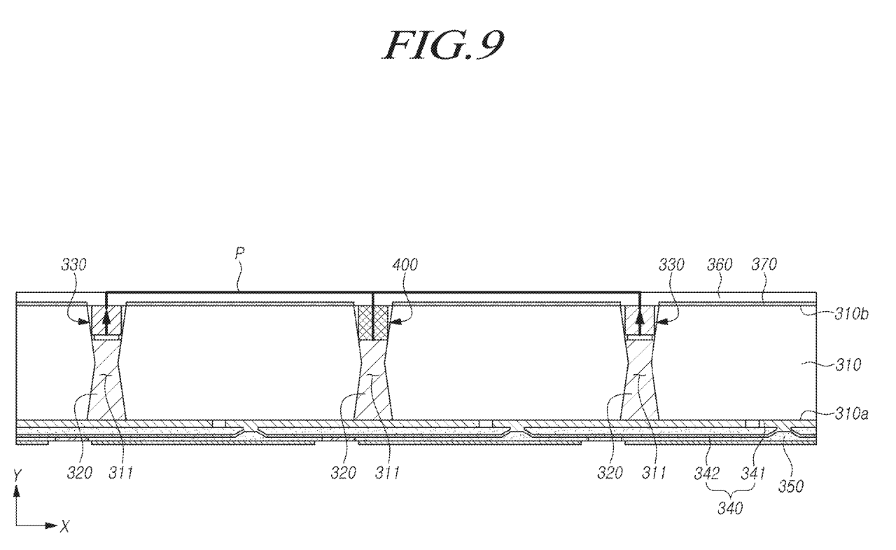

FIG. 9 is a cross-sectional view of a display module according to an embodiment of the disclosure.

The embodiment of FIG. 9 may be selectively combined with the embodiments of FIGS. 1-6, 7A, 7B, and 8.

Referring to FIG. 9, a display module 300 according to an embodiment may include a glass substrate 310, a plurality of through electrodes 320, a plurality of micro LEDs 330, a wiring pattern layer 340, an insulation layer 350, a transparent electrode layer 360, a black matrix layer 370, or a plurality of conductive members 400.

According to an embodiment, the conductive member 400 may be disposed in the through hole 311 of the glass substrate 310. For example, the conductive members 400 may be disposed in a through hole 311 of the plurality of through holes 311 where the micro LEDs 330 are not arranged. The conductive members 400 may be positioned on the upper side of the through electrode 320 within the through hole 311.

According to an embodiment, the conductive member 400 may be electrically connected to the transparent electrode layer 360 and the through electrode 320. The conductive member 400 may be electrically connected to the adjacent plurality of micro LEDs 330 through the transparent electrode layer 360. For example, the conductive member 400 may form an electrical path P together with the adjacent plurality of micro LEDs 330 and the transparent electrode layer 360. In such a case, the current path to the micro LEDs 330 adjacent to each other may be shortened through the electrical path P formed by the conductive member 400, thereby reducing the total resistance of the transparent electrode layer 360.

According to an embodiment, the conductive members 400 may be composed of a conductive material made of a combination of one or more of gold (Au), silver (Ag), copper (Cu), aluminum (Al), tungsten (W), and nickel (Ni). The conductive member 400 may be provided as a one body configuration with the through electrode 320, as opposed to that shown in FIG. 9. For example, the through electrode 320 itself may function as the conductive member 400 as the filling amount of the through electrode 320 is designed differently so that the second electrode portion (e.g., the second electrode portion 320b of FIG. 4) of the through electrode 320 comes into contact with the transparent electrode layer 360.

According to an embodiment of the disclosure, a thin display module 300 can be provided.

According to an embodiment of the disclosure, a vertical micro LED 330 is disposed along with the through electrode 320 in the through hole 311 of the glass substrate 310, so a separate wiring pattern layer (e.g., via, pad, and insulation layer) for electrical connection with the upper electrode of the micro LED 330 may not be required. Accordingly, it is possible to implement the fine pitch response of the micro LEDs 330 and the thinning of the display module 300 owing to the decrease in area of use (or an occupied area) of the wiring pattern layer for the upper side (e.g., surface) of the glass substrate 310 (e.g., the second side 310b of FIG. 4).

According to an embodiment of the disclosure, in connection with the transfer process of the micro LED 330 during the manufacturing process of the display module 300, the vertical micro LED 330 may be disposed and fixed in the through hole 311 of the glass substrate 310, thereby securing the stability of electrical connection of the display module 300.

A display module 300 according to an embodiment of the disclosure may include a glass substrate 310 including a first side 310a and a second side 310b opposite to the first side 310a, and including a plurality of through holes 311 extending from the second side 310b to the first side 310a; a plurality of through electrodes 320 partially filling the through holes 311; and a plurality of micro LEDs 330 disposed in the through holes 311 and electrically connected to the through electrodes 320.

According to an embodiment, the display module 300 may include a first wiring pattern layer 340 disposed on the first side 310a of the glass substrate 310 and electrically connected to the through electrode 320.

According to an embodiment, the display module 300 may include a transparent electrode layer 360 disposed on the second side 310b of the glass substrate 310 and electrically connected to the plurality of micro LEDs 330.

According to an embodiment, the transparent electrode layer 360 may be made of a conductive transparent material including at least one of ITO (indium tin oxide), ITZO (indium tin zinc oxide), silver nano wire (AgNW), and PEDOT (poly-ethylene dioxythiophene).

According to an embodiment, the display module 300 may include a black matrix (BM) layer 370 disposed on the second side 310b of the glass substrate 310 and configured to block light in an area excluding the plurality of micro LEDs 330.

According to an embodiment, the through electrode 320 may include at least one of gold (Au), silver (Ag), copper (Cu), aluminum (Al), tungsten (W), and nickel (Ni).

According to an embodiment, a diameter 311W of the through hole 311 may be greater than a horizontal width 330W of the micro LED 330.

According to an embodiment, the micro LED 330 may include an upper side 330a that is substantially coplanar with the second side 310b of the glass substrate 310.

According to an embodiment, the display module 300 may include a second wiring pattern layer 380 disposed on the second side 310b of the glass substrate 310 and electrically connected to the plurality of micro LEDs 330.

According to an embodiment, the display module 300 may include an insulation layer 350 that is disposed on the first side 310a of the glass substrate 310 and surrounds the first wiring pattern layer 340. The insulation layer 350 may be made of a transparent polymer.

According to an embodiment, the plurality of micro LEDs 330 may include blue micro LEDs. The display module 300 may include a red color conversion layer 390a and a green color conversion layer 390b respectively disposed on two of the three micro LEDs 330, and include a plurality of R/G/B pixels (P) composed of the color conversion layers 390a and 390b and the three micro LEDs 330.

According to an embodiment, the display module may include one or more conductive members 400 disposed in a through hole 311 in which a micro LED 330 is not placed among the plurality of through holes 311. The conductive member 400 may form an electrical path (P) together with the plurality of micro LEDs 330 and the transparent electrode layer 360.

According to an embodiment, the micro LED 330 may be a vertical micro LED.

An electronic device, according to an embodiment of the disclosure may include one or more display modules 300 and a driver IC configured to generate a driving signal to be supplied to the one or more display modules 300. The display module 300 may include a glass substrate 310 including a first side 310a and a second side 310b opposite to the first side 310a, and including a plurality of through holes 311 extending from the second side 310b to the first side 310a; a plurality of through electrodes 320 partially filling the through holes 311; and a plurality of micro LEDs 330 disposed in the through holes 311 and electrically connected to the through electrodes 320.

According to an embodiment, the display modules 300 may include a first wiring pattern layer 340 disposed on the first side 310a of the glass substrate 310 and electrically connected to the through electrode 320.

According to an embodiment, the display modules 300 may include a transparent electrode layer 360 disposed on the second side 310b of the glass substrate 310 and electrically connected to the plurality of micro LEDs 330.

According to an embodiment, the display modules 300 may include a black matrix (BM) layer 370 disposed on the second side 310b of the glass substrate 310 and configured to block light in regions excluding the plurality of micro LEDs 330.

According to an embodiment, a diameter 311W of the through hole 311 may be greater than a horizontal width 330W of the micro LED 330.

According to an embodiment, the micro LED 330 may include an upper side 330a that is substantially coplanar with the second side 310b of the glass substrate 310.

According to an embodiment, the micro LED 330 may be a vertical micro LED.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A display module, comprising:
a glass substrate including:
a first surface, a second surface opposite to the first surface, and a plurality of through holes extending from the second surface to the first surface;
a plurality of through electrodes, each through electrode partially filling a through hole among the plurality of through holes; and
a plurality of micro light emitting diodes (LEDs), each micro LED disposed in a through hole among the plurality of through holes, and electrically connected to a through electrode among the plurality of through electrodes.

2. The display module of claim 1, further comprising:
a first wiring pattern layer disposed on the first surface of the glass substrate, the first wiring pattern layer electrically connected to the plurality of through electrodes.

3. The display module of claim 2, further comprising:
an insulation layer disposed on the first surface of the glass substrate,
wherein the insulation layer surrounds the first wiring pattern layer, and
wherein the insulation layer is made of a transparent polymer.

4. The display module of claim 1, further comprising:
a transparent electrode layer disposed on the second surface of the glass substrate, the transparent electrode layer electrically connected to the plurality of micro LEDs.

5. The display module of claim 4, wherein the transparent electrode layer is composed of a conductive transparent material including at least one of ITO (indium tin oxide), ITZO (indium tin zinc oxide), silver nano wire (AgNW), and PEDOT (poly-ethylene dioxythiophene).

6. The display module of claim 4, further comprising:
one or more conductive members disposed in a through hole in which a micro LED is not placed among the plurality of through holes,
wherein the one or more conductive members forms an electrical path together with the plurality of micro LEDs and the transparent electrode layer.

7. The display module of claim 1, further comprising:
a black matrix (BM) layer disposed on the second surface of the glass substrate, the BM layer configured to block light in an area excluding the plurality of micro LEDs.

8. The display module of claim 1, wherein each through electrode among the plurality of through electrodes includes at least one of gold (Au), silver (Ag), copper (Cu), aluminum (Al), tungsten (W), and nickel (Ni).

9. The display module of claim 1, wherein a diameter of each through hole among the plurality of through holes is greater than a horizontal width of a corresponding micro LED among the plurality of micro LEDs.

10. The display module of claim 1, wherein each micro LED among the plurality of micro LEDs includes an upper surface that is substantially coplanar with the second surface of the glass substrate.

11. The display module of claim 1, further comprising:
a second wiring pattern layer disposed on the second surface of the glass substrate, the second wiring pattern layer electrically connected to the plurality of micro LEDs.

12. The display module of claim 1,
wherein the plurality of micro LEDs include blue micro LEDs, and
wherein the display module further comprises:
a plurality of R/G/B pixels, each pixel composed of three micro LEDs, a red color conversion layer disposed on a first micro LED of the three micro LEDs, and a green color conversion layer disposed on a second micro LED of the three micro LEDs.

13. The display module of claim 1, wherein each micro LED of the plurality of micro LEDs is a vertical micro LED.

14. An electronic device comprising:
one or more display modules; and
a driver integrated circuit (IC) configured to generate a driving signal to be supplied to the one or more display modules,
wherein each display module among the one or more display modules comprises:
a glass substrate including a first surface and a second surface opposite to the first surface, the glass substrate including a plurality of through holes extending from the second surface to the first surface,
a plurality of through electrodes, each through electrode partially filling a through hole among the plurality of through holes, and
a plurality of micro light emitting diodes (LEDs), each LED disposed in a through hole among the plurality of through holes and electrically connected to a through electrode among the plurality of through electrodes.

15. The electronic device of claim 14, further comprising:
a first wiring pattern layer disposed on the first surface of the glass substrate and electrically connected to the plurality of through electrodes.

16. The electronic device of claim 14, further comprising:
a transparent electrode layer disposed on the second surface of the glass substrate, the transparent electrode layer electrically connected to the plurality of micro LEDs.

17. The electronic device of claim 14, further comprising:
a black matrix (BM) layer disposed on the second surface of the glass substrate, the BM layer configured to block light in regions excluding the plurality of micro LEDs.

18. The electronic device of claim 14, wherein a diameter of each through hole among the plurality of through holes is greater than a horizontal width of the corresponding micro LED among the plurality of micro LEDs.

19. The electronic device of claim 14, wherein each micro LED among the plurality of LEDs includes an upper surface that is substantially coplanar with the second surface of the glass substrate.

20. The electronic device of claim 14, wherein each micro LED among the plurality of micro LEDs is a vertical micro LED.
